(19) United States
(12) Patent Application Publication
(10) Pub. No.: US 2025/0237496 A1
(43) Pub. Date: Jul. 24, 2025

(54) Methods And Systems For Reflectometry Based Measurements Of Deep, Large Pitch Semiconductor Structures

(71) Applicant: KLA Corporation, Milpitas, CA (US)

(72) Inventors: Kevin Peterlinz, San Ramon, CA (US); Jinchuan Shi, Milpitas, CA (US); Phillip R. Atkins, San Jose, CA (US); Shankar Krishnan, Cupertino, CA (US); Giulio Baldi, Villasanta (IT)

(21) Appl. No.: 18/977,795

(22) Filed: Dec. 11, 2024

Related U.S. Application Data
(60) Provisional application No. 63/623,145, filed on Jan. 19, 2024.

(51) Int. Cl. G01B 11/22

(52) U.S. Cl. CPC G01B 11/22; G01B 2210/56

(57) ABSTRACT

Methods and systems for performing spectroscopic reflectometry based measurements of deep, large pitch semiconductor structures at high throughput are presented herein. A multi-step regression algorithm employs a non-periodic electromagnetic (EM) solver, i.e., an EM solver that does not rely on a Fourier based analysis. The multi-step regression algorithm utilizes both incoherent and coherent reflections resulting in faster and more accurate estimates of parameters of interest, including the depth of deep trench or deep hole structures. The coherent sum of reflection coefficients captures height differences among sub-structures of a structure under measurement, whereas an incoherent sum of reflection coefficients largely ignores the height differences. Estimated values of one or more parameters of interest generated by a prior regression are employed as seed values of floating parameters, fixed valued parameters, or both, in a subsequent regression employed to refine the estimated values of the parameters of interest.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput without the risk of sample destruction. A number of optical metrology based techniques including scatterometry and reflectometry implementations and associated analysis algorithms are commonly used to characterize critical dimensions, film thicknesses, composition, overlay and other parameters of nanoscale structures.

Flash memory architectures are transitioning from two dimensional floating-gate architectures to fully three dimensional geometries. In some examples, film stacks and etched structures are very deep (e.g., ten micrometers in depth, or more). Such high aspect ratio structures create challenges for film and CD measurements. The ability to measure the critical dimensions that define the shapes of holes and trenches of these structures is critical to achieve desired performance levels and device yield. Current metrology systems struggle to measure critical dimensions and depths of high aspect ratio structures, such as Through-Silicon Via (TSV) structures, due to lack of light penetration and insufficient optical resolution.

High-throughput, optical metrology techniques are being explored as measurement solutions for high aspect ratio structures. Typical optical metrology techniques, such as spectroscopic reflectometry, ellipsometry, or scatterometry are indirect methods of measuring physical properties of the specimen under inspection. In most cases, the raw measurement signals (e.g., αₘₑₐₛ and βₘₑₐₛ) cannot be used to directly determine the physical properties of the specimen. The nominal measurement process consists of parameterization of the structure (e.g., film thicknesses, critical dimensions, material properties, etc.) and the machine (e.g., wavelengths, angles of incidence, polarization angles, etc.). A measurement model is created that attempts to predict the measured values (e.g., αₘₑₐₛ and βₘₑₐₛ). As illustrated in equations (1) and (2), the model includes parameters associated with the machine (P_{machine}) and the specimen (P_{specimen}).

$${α}_{model} = f ( {P}_{machine} , {P}_{specimen} ) \qquad ( 1 )$$

$${β}_{model} = g ( {P}_{machine} , {P}_{specimen} ) \qquad ( 2 )$$

Machine parameters are parameters used to characterize the metrology tool. Exemplary machine parameters include angle of incidence (AOI), analyzer angle (A₀), polarizer angle (P₀), illumination wavelength, numerical aperture (NA), compensator or waveplate (if present), etc. Specimen parameters are parameters used to characterize the specimen. For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the machine parameters are treated as known, fixed parameters and one or more of the specimen parameters are treated as unknown, floating parameters.

In some examples, the floating parameters are resolved by an iterative process (e.g., regression) that produces the best fit between theoretical predictions and experimental data. The unknown specimen parameters, P_{specimen}, are varied and the model output values (e.g., α_{model} and β_{model}) are calculated until a set of specimen parameter values are determined that results in a close match between the model output values and the experimentally measured values (e.g., αₘₑₐₛ and βₘₑₐₛ). In a model based measurement application such as spectroscopic reflectometry on a CD specimen, a regression process is employed to identify specimen parameter values that minimize the differences between the model output values and the experimentally measured values for a fixed set of machine parameter values.

In many examples, gradient-based nonlinear regression algorithms or non-gradient nonlinear regression algorithms, such as surrogate optimization, are employed to estimate values of parameters of interest. The regression based algorithms calculate the simulated measurement signals, compute a residual difference between the experimentally measured signals and the simulated measurement signals, and compute derivatives of the residual with respect to the parameters of interest (in the case of gradient based searches). The regression based algorithms employ the computed residual and derivatives to update the values of the parameters of interest. This process is iterated until the simulated measurement signals converge to the experimentally measured signals within an acceptable error threshold.

Accurately computing simulated measurement signals is one of the most critical steps of the regression process. This step directly affects the computational speed and final accuracy of the regression algorithm. Traditionally, a rigorous coupled wave analysis (RCWA) electromagnetic solver is employed to compute the simulated measurement signals. An RCWA-based electromagnetic solver works well on measurement targets characterized by relatively small critical dimensions. However, practical limitations of an RCWA-based electromagnetic solver emerge when measurement targets have dimensions or features that are electrically large, e.g., periodic targets characterized by a pitch that is 5-10× the longest wavelength of illumination light employed to perform the measurement.

Measurements of targets having electrically large pitch using an RCWA-based electromagnetic solver require the calculation of a large number of Fourier orders to achieve acceptable accuracy. Unfortunately, the computational resources required to execute an RCWA-based electromagnetic solver scale by an order of approximately three with the number of Fourier modes, and the amount of memory scales by an order of approximately two with the number of Fourier modes. Moreover, existing methods to accelerate the computations of an RCWA-based electromagnetic solver require even larger amounts of memory. Thus, the exclusive use of an RCWA-based electromagnetic solver to measure electrically large pitch targets with acceptable accuracy is practically infeasible due to excessively high computational costs.

Furthermore, the measurement of depth of deep, large pitch structures, e.g., deep holes and trenches, is often not possible using an RCWA-based electromagnetic solver because deep holes and trenches lead to a large number of nearly degenerate solutions. Physically, hole or trench depth is determined by the phase difference between a reflection off of the top of the hole or trench versus a reflection off of the bottom of the hole or trench. For holes or trenches with a very large electrical depth, the phase wraps many times as the electromagnetic wave travels to the bottom of the structure. This causes a large number of nearly degenerate solutions. As a result, a regression employing an RCWA-based electromagnetic solver often fails to converge to an accurate solution because the algorithm easily converges to false local minima.

In summary, the measurement of depth of deep, large pitch targets is not feasible based on the current regression techniques which rely on RCWA-based electromagnetic solvers. Optical metrology systems must meet high precision and accuracy requirements for increasingly complex targets at high throughput to remain cost effective. In this context, the accurate simulation of measurement signals has emerged as a critical, performance limiting issue in the design of optical metrology systems suitable for deep, high aspect ratio structures. Thus, improved metrology systems and methods to overcome these limitations are desired.

### SUMMARY

Methods and systems for performing spectroscopic reflectometry based measurements of deep, large pitch semiconductor structures at high throughput are presented herein. A multi-step regression algorithm employs a non-periodic electromagnetic (EM) solver, i.e., an EM solver that does not rely on a Fourier based analysis. The multi-step regression algorithm utilizes both incoherent and coherent reflections resulting in faster and more accurate estimates of parameters of interest, including the depth of deep trench or deep hole structures.

In some embodiments, a spectroscopic reflectometer includes a broadband illumination source that generates illumination light ranging from the deep ultraviolet to short infrared wavelengths, e.g., 190 nm to 1000 nm. The illumination light includes wavelengths that are less than half the lateral dimension characterizing the width of the deep structural feature under measurement, e.g., trench width, hole width, etc. In addition, the spectroscopic reflectometer includes low Numerical Aperture (NA) optics to realize a relatively large size illumination and collection spot to improve fringe contrast, resolution, and signal fidelity from measurements of large pitch structures and deep structures, e.g., periodic pitch up to 8 micrometers and depth ranging from 10 micrometers to 75 micrometers. The spectroscopic reflectometer employs a high speed and high resolution detector to improve spectral resolution and throughput.

In one aspect, a regression is employed to estimate values of one or more parameters of interest using a non-periodic solver to simulate measurement signals. The measurement signals are generated based on a coherent sum of the reflection coefficients associated with each of a plurality of sub-structures comprising a structure under measurement. The coherent sum of reflection coefficients captures height differences among sub-structures of a structure under measurement, e.g., height differences between a trench and a line or a hole and a line, whereas an incoherent sum of reflection coefficients largely ignores the height differences.

In another aspect, a multi-step regression is employed to estimate a value of a parameter of interest. The multi-step regression includes multiple regressions, where the estimated values of one or more parameters of interest generated by a first regression are employed as seed values of floating parameters, fixed valued parameters, or both, in a subsequent regression employed to refine the estimated values of the parameters of interest. Multi-step regression enables convergence to accurate values of one or more parameters of interest without becoming trapped in local minima. In particular, a multi-step regression approach is critical to converge on an accurate estimated value of depth of a deep structure, e.g., a deep hole or deep trench structure. In addition, the multi-step regression approach provides accurate estimated values of other critical dimensions of a deep structure, e.g., film thicknesses, line width, etc.

In some examples, a first regression analysis is performed to arrive at a first set of estimated values of one or more parameters of interest. The estimated values of the one or more parameters of interest are employed as seed values of floating parameters, fixed valued parameters, or both, for a subsequent regression analysis. In some examples, different parameters of interest are floated in the subsequent regression analysis. In some examples, the same parameters of interest are floated in the subsequent regression analysis.

In some examples, a different electromagnetic solver is employed in a subsequent regression analysis than the electromagnetic solver employed in a prior regression analysis. In some other examples, the same electromagnetic solver is employed in both the prior regression analysis and the subsequent regression analysis.

In some examples, the simulated measurement signals are generated based on an incoherent sum of the reflection coefficients associated with each of a plurality of sub-structures comprising a structure under measurement in the first regression analysis, and the simulated measurement signals are generated based on a coherent sum of the reflection coefficients associated with each of a plurality of sub-structures comprising a structure under measurement in the subsequent regression analysis.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an exemplary metrology system 100 for performing spectroscopic reflectometry measurements of stacked semiconductor structures in accordance with the methods described herein.

FIG. 2 depicts a diagram illustrative of a deep, large pitch semiconductor structure measurement engine 160 on one embodiment.

FIG. 3 is a diagram illustrative of a cross-sectional view of a deep, large pitch trench structure 200 in one embodiment.

FIG. 4 is a plot illustrative of spectral signals associated with measurements of trench structure 200 depicted in FIG. 3 by SR metrology system 100. Spectral signals associated with a transverse magnetic (TM) measurement channel and a transverse electric (TE) measurement channel of SR metrology system 100 are illustrated.

FIG. 5 is a plot illustrative of measured spectral signals associated with a TM measurement channel of SR metrology system 100 and corresponding simulated measurement signals generated based on an incoherent sum of the reflection coefficients associated with the sub-structures of trench structure 200 after fitting of trench fraction, trench depth, line fraction, and film thickness parameters.

FIG. 6 is a plot illustrative of measured spectral signals associated with a TM measurement channel of SR metrology system 100 and corresponding simulated measurement signals generated based on an coherent sum of the reflection coefficients associated with the sub-structures of trench structure 200 after fitting of trench fraction, trench depth, line fraction, and film thickness parameters.

FIG. 7 is a diagram illustrative of a perspective view of a deep, large pitch hole structure 210 in one embodiment.

FIG. 8 is a plot illustrative of measured spectral signals associated with a TM measurement channel of SR metrology system 100 and corresponding simulated measurement signals generated based on an incoherent sum of the reflection coefficients associated with the sub-structures of hole structure 210 after fitting of line fraction, TCD, BCD, and the film thickness parameters.

FIG. 9 is a plot illustrative of the measured spectral signals illustrated by FIG. 8 mapped to the inverse wavelength domain.

FIG. 10 is a plot illustrative of a Fast Fourier Transform (FFT) of the mapped spectral signals of FIG. 9.

FIG. 11 is a plot illustrative of measured spectral signals associated with a TM measurement channel of SR metrology system 100 and corresponding simulated measurement signals generated based on a coherent sum of the reflection coefficients associated with the sub-structures of hole structure 210 after fitting of hole fraction, hole depth, line fraction, TCD, BCD, and the film thickness parameters.

FIG. 12 illustrates a method 300 of performing spectroscopic reflectometry based measurements of stacked semiconductor structures as described herein.

### DETAILED DESCRIPTION

Reference will now be made in detail to background examples and some embodiments of the invention, examples of which are illustrated in the accompanying drawings.

Methods and systems for performing spectroscopic reflectometry based measurements of deep, large pitch semiconductor structures at high throughput are presented herein. A multi-step regression algorithm employs a non-periodic electromagnetic (EM) solver, i.e., an EM solver that does not rely on a Fourier based analysis. The multi-step regression algorithm utilizes both incoherent and coherent reflections resulting in faster and more accurate estimates of parameters of interest, including the depth of deep trench or deep hole structures.

In one aspect, a semiconductor metrology system includes a spectroscopic reflectometer suitable for high throughput measurements of deep, large pitch semiconductor structures. In some embodiments, the spectroscopic reflectometer includes a broadband illumination source that generates illumination light ranging from the deep ultraviolet to short infrared wavelengths, e.g., 190 nm to 1000 nm. The illumination light includes wavelengths that are less than half the lateral dimension characterizing the width of the deep structural feature under measurement, e.g., trench width, hole width, etc. In addition, the spectroscopic reflectometer includes low Numerical Aperture (NA) optics to realize a relatively large size illumination and collection spot to improve fringe contrast, resolution, and signal fidelity from measurements of large pitch structures and deep structures, e.g., periodic pitch up to 8 micrometers and depth ranging from 10 micrometers to 75 micrometers. The spectroscopic reflectometer employs a high speed and high resolution detector to improve spectral resolution and throughput.

In some embodiments, large pitch targets under measurement include a deep structure, e.g., a trench or a hole, having a depth ranging from 10 micrometers to 75 micrometers, and a periodic pitch up to 8 micrometers. In some of these embodiments, the large pitch targets include a film stack on top of the CD structure including multiple layers fabricated using different materials and thicknesses.

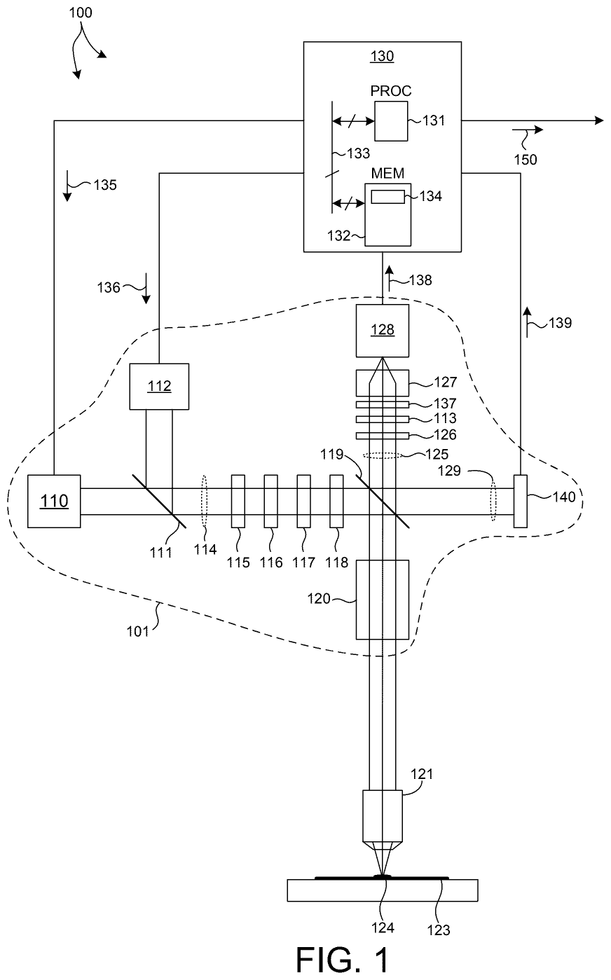

FIG. 1 depicts a simplified diagram of a spectroscopic reflectometry (SR) based metrology system 100 in one embodiment. As depicted in FIG. 1, the spectroscopic reflectometer 101 is operable at any wavelength in a range of wavelengths from the visible to short infrared portions of the electromagnetic spectrum.

In the embodiment depicted in FIG. 1, spectroscopic reflectometer 101 includes a laser sustained plasma (LSP) light source 110 and a mercury lamp light source 112. LSP light source 110 emits illumination light at wavelengths in the deep ultraviolet, visible, near-infrared, and mid-infrared spectra to penetrate through deep structures. Typically, an LSP light source emits light in a wavelength range from 150 nanometers to 2500 nanometers. The pump laser of the LSP light source may be continuous wave or pulsed. In the embodiment depicted in FIG. 1, a single LSP pump laser source is employed. However, in general an LSP light source 110 may employ more than one LSP pump laser source to excite photons over different wavelength ranges, thereby enhancing the brightness and power of portions of the plasma spectrum or the entire plasma spectrum. Each LSP pump laser source generates pump light focused by focusing optics to a focal point. The focused pump light sustains a plasma contained by a plasma chamber. The plasma chamber includes one or more exit ports through which the emitted light is transmitted onto the optical system. The plasma generates broadband spectrum light over a wavelength range from vacuum ultra-violet to mid-infrared. A LSP light source can produce significantly more radiance than an arc lamp across the entire wavelength range from 120 nanometers to 20,000 nanometers. As depicted in FIG. 1, control signals 135 are communicated from computing system 130 to control LSP light source 110. In response, LSP light source 110 adjusts its optical output, e.g., flux, spectral range, etc., in accordance with command signals 135.

Mercury lamp light source 112 also emits light over a broad range of wavelengths from 250 nanometers through short infrared wavelengths. Computing system 130 communicates control signal 136 to mercury lamp light source 112. In response, mercury lamp light source 112 adjusts its optical output, e.g., flux, spectral range, etc., in accordance with command signals 136.

Computing system 130 also communicates control signals (not shown) to flip-in mirror 111 to select light source 110 or light source 112 by movement of flip-in mirror 111. In this manner computing system 130 controls which light source provides illumination light to a wafer under measurement.

In general, a SR system may include a single light source or a combination of a plurality of broadband or discrete wavelength light sources. The light sources may be selectable and the output of each of these light sources may be controlled by computing system 130 to emit illumination light 114 having desired optical characteristics, e.g., flux, wavelength ranges, etc. The light generated by an illumination source includes a continuous spectrum or parts of a continuous spectrum, from ultraviolet to mid-infrared (e.g., visible to short infrared). In general, a SR system may include any of a LSP light source, an arc lamp light source, e.g., a xenon arc lamp, a mercury arc lamp, etc., an incandescent light source, a supercontinuum laser source, an infrared supercontinuum source, a set of lasers, e.g., a set of quantum cascade lasers, an infrared helium-neon laser source, a deuterium lamp, a thermal light source, e.g., globar light source, a quantum cascade laser source, any other suitable light source, or any combination thereof.

In a further aspect, an SR system employs illumination optics having a relatively low numerical aperture (NA) to direct illumination light from one or more illumination sources to the wafer under measurement. In some embodiments, the SR illumination optics limit the numerical aperture of illumination light projected onto a wafer to 0.04 to 0.08. This minimizes overlap, i.e., crosstalk, among diffraction orders over one or more wavelengths. In addition, the relatively low NA enables a relatively large illumination spot size at the wafer, e.g., 20 micrometers to 100 micrometers. The relatively large illumination spot size enables measurement of large pitch structures.

As depicted in FIG. 1, illumination optical elements direct SR illumination light 114 from a selected SR illumination light source toward wafer 123. In the embodiment depicted in FIG. 1, SR illumination light 114 is collimated by illumination optics 115 and filtered by optical filtering elements 116. In addition, SR illumination light 114 is passed through an illumination field stop 117 and pupil aperture 118 to define the shape, size, and divergence of the illumination beam. In general, the illumination optical elements include a field stop, a pupil aperture, and optical elements having reflective focusing power. In addition, the illumination optical elements may also include optional beam conditioning optics, e.g., filters, masks, apodizers, etc.

Beam splitter 119 directs the majority of the SR illumination beam 114 toward polarizing optics 120, and transmits a small portion 129 of the SR illumination beam toward beam monitor 140. Beam monitor 140 communicates signals 139 indicative of the shape, size, and divergence of the illumination beam to computing system 130.

Computing system 130 receives the beam monitor signals 139 and generates command signals (not show) communicated to one or more of the illumination optical elements that cause the illumination optical elements to adjust the properties of the illumination beam to match the desired beam properties, e.g., beam shape, size, and divergence.

Polarizing optical device 120 imposes a desired polarization state on the illumination light directed to wafer 123. Polarizing optical device 120 includes one or more polarizing elements and an optional compensator. Polarizing optical device 120 may be fixed, rotatable to different fixed orientations, or continuously rotating at a desired angular velocity. Similarly, the optional compensator may be fixed, rotatable to different fixed orientations, or continuously rotating at a desired angular velocity. In one embodiment, polarizing elements of polarizing optical device 120 include a Magnesium Fluoride Rochon polarizer. In some embodiments, the optional compensator is a quartz waveplate, a Magnesium Fluoride waveplate, a Calcium Fluoride K-prism, or a Calcium Fluoride double Fresnel rhomb. In other embodiments, polarizing optical device 120 is located before beam splitter 119.

After polarization, SR illumination light 114 passes to objective 121. Objective 121 focuses the collimated illumination light onto one or more structures 124 disposed on wafer 123. In some embodiments, the illumination source, e.g., illumination source 112, illumination field stop 117, and wafer 123 are field conjugates. In the embodiment depicted in FIG. 1, the angle of incidence of the focused SR illumination light is at or near normal with respect to wafer 123. However, in general, off-axis illumination may be contemplated within the scope of this patent document.

In some embodiments, the SR illumination optical elements and objective 121 generate an illumination spot size at wafer 123 characterized by a dimension of largest extent of 30-50 micrometers. In some other embodiments, the SR illumination optical elements and objective 121 generate an illumination spot size at wafer 123 characterized by a dimension of largest extent of 20-100 micrometers. In these embodiments, measurements of deep, large pitch structures having a pitch of 10 micrometers or less are enabled.

Objective 121 also collects SR collected light 125 from one or more structures 124 disposed on wafer 123 in response to incident SR illumination light 114. Objective 121 collimates SR collected light 125 and directs the collimated SR collected light 125 towards beam splitter 119. Beam splitter 119 directs SR collected light 125 towards collection optical elements, which, in turn, direct SR collected light 125 onto spectrometer 128. In some embodiments, SR illumination light 114 and SR collected light 125 are collocated at beam splitter 119. However, in some other embodiments, SR illumination light 114 and SR collected light 125 are not collocated at beam splitter 119.

As depicted in FIG. 1, collection optical elements include collection field stop 126, collection pupil aperture 113, and focusing optics 127. Collection field stop 126 defines the size and shape of the collection beam. Collection pupil aperture 113 defines the divergence of the collection beam. In some embodiments, collection pupil aperture 113 limits the numerical aperture of SR collected light 125 from wafer 123 to 0.01 to 0.04. This relatively small collection NA improves fringe contrast, resolution, and spectral fidelity associated with measurements of large pitch targets and deep target structures. Focusing optics 127 focus SR collected light 125 at or near a spectrometer slit (not shown) of spectrometer 128. In some embodiments, wafer 123, collection field stop 126, the spectrometer slit of spectrometer 128, and the active surface of the detector of spectrometer 128 are field conjugates.

In general, the collection optical elements include a field stop, a pupil aperture, and optical elements having reflective focusing power. In addition, the illumination optical elements may also include optional beam conditioning optics, e.g., filters, masks, apodizers, etc.

In addition, analyzer 137 is located in the collection optical path between wafer 123 and detector 128. Analyzer 137 includes an analyzer optical element and an optional compensator. Analyzer 137 may be fixed, rotatable to different fixed orientations, or continuously rotating at a desired angular velocity. Similarly, the optional compensator may be fixed, rotatable to different fixed orientations, or continuously rotating at a desired angular velocity. In one embodiment, elements of the analyzer include a Magnesium Fluoride Rochon polarizer. In some embodiments, the optional compensator is a quartz waveplate, a Magnesium Fluoride waveplate, a Calcium Fluoride K-prism, or a Calcium Fluoride double Fresnel rhomb.

Spectrometer 128 includes a spectrometer slit, a dispersive element, one or more optics having reflective focusing power, and a detector. The spectrometer slit receives and directs focused SR collection light 125 to a dispersive element, e.g., a diffraction grating. The dispersive element disperses SR collected light into discrete wavelengths on the active surface of a detector. The detector of spectrometer 128 receives SR collected light 125 from one or more wavelengths, one or more polarization states, or both, at different locations on the active surface of the detector.

In one further aspect, spectrometer 128 resolves signals from different depths of a structure 124 under measurement. For example, short wavelength SR illumination light only penetrates top layers of the structure 124 under measurement, while longer wavelength SR illumination light penetrates deeper layers of the structure 124 under measurement. In this manner, short wavelength SR collection light includes information from top layers, while longer wavelength SR collection light includes information from deeper layers. Spectrometer 128 is wavelength resolved, and thus, separates signal information associated with top layers and deeper layers of the structure under measurement.

In some embodiments, the detector of spectrometer 128 is sensitive to vacuum ultraviolet, deep ultraviolet, ultraviolet, visible, and near-infrared light including any wavelength within a range of 120 nanometers to 2.5 micrometers, e.g., 170 nanometers to 1.0 micrometer. In some embodiments, the detector of spectrometer 128 is a charge coupled device (CCD). However, in general, other two dimensional detector technologies may be contemplated (e.g., a position sensitive detector (PSD), a photovoltaic detector, etc.). The detector of spectrometer 128 converts the SR collected light 125 into electrical signals indicative of the spectral intensity of the incident light.

As depicted in FIG. 1, the detector of spectrometer 128 generates detected signals 138 indicative of the optical response of the measured structures on wafer 123 to the illumination light 114. The detector communicates detected signals 138 to computing system 130. Computing system 130 processes the signals from the detector of spectrometer 128 and estimates values 150 of one or more parameters of interest characterizing the measured structure(s) 124 based on detected signals 138.

In some embodiments, the SR measurements described herein include wavelengths ranging from visible to short infrared. However, in some other embodiments, the SR measurements described herein include wavelengths in the mid-infrared and infrared portions of the electromagnetic spectrum.

In some embodiments, measured spectra include different ranges of wavelengths, e.g., ultraviolet, visible, near infrared and mid-infrared wavelengths. In some of these embodiments, an SR subsystem includes multiple measurement channels to perform simultaneous measurements of a semiconductor structure with different wavelength light with the same alignment conditions. In this manner, machine errors, such as wavelength errors, are uniformly corrected across all measured wavelengths. These features, individually, or in combination, enable high throughput measurements of deep, large pitch structures with high throughput, precision, and accuracy.

By measuring with multiple measurement channels of a single metrology system spanning a broad range of illumination wavelengths (e.g., 190 nanometers to 2.5 micrometers), precise characterization of complex three dimensional structures is enabled. In general, relatively long wavelengths penetrate deep into a structure and provide suppression of high diffraction orders when measuring structures with relatively large pitch. Relatively short wavelengths provide precise dimensional information about structures accessible to relatively short wavelengths (i.e., top level layers) as well as relatively small CD and roughness features. In some examples, longer wavelengths enable measurement of dimensional characteristics of targets with relatively rough surfaces or interfaces due to lower sensitivity of longer wavelengths to roughness. In some examples, shorter wavelengths enable measurement of large pitch structures using non-periodic solvers because the illumination of large pitch structures under measurement with shorter wavelengths deemphasizes the influence of adjacent periodic cells. Under these conditions, the periodic properties of a metrology target under measurement are safely ignored, thus enabling the use of non-periodic solvers.

Metrology system 100 includes computing system 130 configured to receive detected signals 138 including the spectral response of wafer 123 to illumination 114. Furthermore, computing system 130 determines an estimated value 150 of a parameter of interest of the measured structure(s) based on detected signals 138 as described herein.

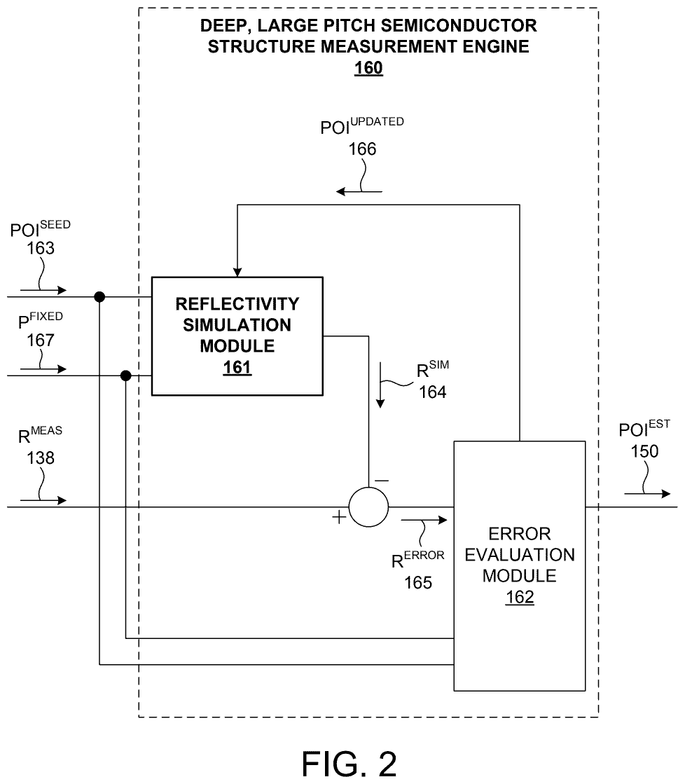

FIG. 2 depicts a diagram illustrative of a deep, large pitch semiconductor structure measurement engine 160 on one embodiment. In some embodiments, computing system 130 is configured as deep, large pitch semiconductor structure measurement engine 160. As depicted in FIG. 2, measured spectral signals, R^{MEAS} 138, e.g., measured spectral signals 138 generated by spectrometer 128 depicted in FIG. 1, are received by deep, large pitch semiconductor structure measurement engine 160. In an initial iteration of a regression analysis performed by deep, large pitch semiconductor structure measurement engine 160, reflectivity simulation module 161 generates simulated spectral signals, R^{SIM} 164, based on seed values, POI^{SEED} 163, corresponding to one or more floating parameters of interest and fixed values of other model parameters, P^{FIXED} 167. As depicted in FIG. 2, deep, large pitch semiconductor structure measurement engine 160 computes a difference between the measured spectral signals, R^{MEAS} 138, and the simulated spectral signals, R^{SIM} 164, to compute a residual error, R^{ERROR} 165.

Error evaluation module 162 compares the computed residual error to a predetermined threshold value. If the computed residual error is equal to or less than the predetermined threshold value, error evaluation module 162 communicates the estimated values of the one or more parameters of interest, POI^{EST} 150, as the current values of the one or more parameters of interest employed by reflectivity simulation module 161 to compute the simulated spectral signals, R^{SIM} 164, in the current iteration of the regression. If the computed residual error is greater than the predetermined threshold value, error evaluation module 162 computes updated values of the one or more parameters of interest, POI^{UPDATED} 166, and communicates POI^{UPDATED} 166 to reflectivity simulation module 161. Reflectivity simulation module 161 computes simulated spectral signals, R^{SIM} 164, based on the updated values, POI^{UPDATED} 166, corresponding to one or more parameters of interest. The regression continues in an iterative loop until the computed residual error is equal to or less than the predetermined threshold value, or a maximum allowed number of iterations is reached.

In one aspect, a regression is employed to estimate values of one or more parameters of interest using a non-periodic solver to simulate measurement signals. The measurement signals are generated based on a coherent sum of the reflection coefficients associated with each of a plurality of sub-structures comprising a structure under measurement. The coherent sum of reflection coefficients captures height differences among sub-structures of a structure under measurement, e.g., height differences between a trench and a line or a hole and a line, whereas an incoherent sum of reflection coefficients largely ignores the height differences.

In the embodiment depicted in FIG. 2, reflectivity simulation module 161 implements a non-periodic electromagnetic solver to generate the simulated spectral signals, R^{SIM} 164, based on the fixed values and floating values of the model parameters. By employing relatively short wavelength illumination for measurements of large pitch targets, the periodicity of the target is safely ignored, thus enabling the use of non-periodic electromagnetic solvers.

Non-periodic electromagnetic solvers enable more accurate simulation of measurement signals with dramatically reduced computational effort and memory resources compared to an RCWA electromagnetic solver. In some examples, a high-frequency approximation method is employed, e.g., Geometric Optics (GO) with the Unified Theory of Diffraction (UTD). High-frequency approximation methods have shown excellent time to solution (TTS) results for measurements of deep, large pitch targets. In some examples, Physical Optics (PO), Shooting Bouncing Rays (SBR), and other sophisticated diffraction algorithms are employed to efficiently and accurately compute simulated measurement signals. In some examples, a full wave electromagnetic solver is employed. In particular, the Method of Moments (MoM) with a Body of Revolution (BOR) model is feasible to simulate measurement signals generated from through silicon via structures. The non-periodic solvers described herein are provided as non-limiting, exemplary candidates for successful measurement of large pitch, deep structures. In general, any suitable non-periodic solver may be contemplated within the scope of this patent document.

In another aspect, a multi-step regression is employed to estimate a value of a parameter of interest. The multi-step regression includes multiple regressions, where the estimated values of one or more parameters of interest generated by a first regression are employed as seed values of floating parameters, fixed valued parameters, or both, in a subsequent regression employed to refine the estimated values of the parameters of interest. Multi-step regression enables convergence to accurate values of one or more parameters of interest without becoming trapped in local minima. In particular, a multi-step regression approach is critical to converge on an accurate estimated value of depth of a deep structure, e.g., a deep hole or deep trench structure. In addition, the multi-step regression approach provides accurate estimated values of other critical dimensions of a deep structure, e.g., film thicknesses, line width, etc.

In some examples, deep, large pitch semiconductor structure measurement engine 160 is configured to perform multiple regression steps.

In some examples, a first regression analysis is performed to arrive at a first set of estimated values of one or more parameters of interest. The estimated values of the one or more parameters of interest are employed as seed values of floating parameters, fixed valued parameters, or both, for a subsequent regression analysis. In some examples, different parameters of interest are floated in the subsequent regression analysis. In some examples, the same parameters of interest are floated in the subsequent regression analysis.

In some examples, reflectivity simulation module 161 employs a different electromagnetic solver in the subsequent regression analysis than the electromagnetic solver employed in the first regression analysis. In some other examples, the same electromagnetic solver is employed in both the first regression analysis and the subsequent regression analysis.

In some examples, the simulated measurement signals are generated based on an incoherent sum of the reflection coefficients associated with each of a plurality of sub-structures comprising a structure under measurement in the first regression analysis, and the simulated measurement signals are generated based on a coherent sum of the reflection coefficients associated with each of a plurality of sub-structures comprising a structure under measurement in the subsequent regression analysis.

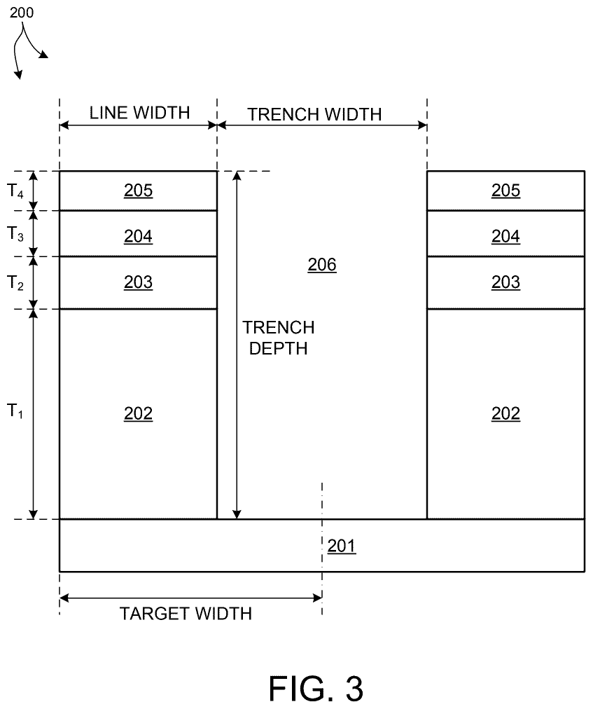

FIG. 3 is a diagram illustrative of a cross-sectional view of a deep, large pitch trench structure 200 in one embodiment. The rectangular trench target is represented as a two-dimensional structure having no shape variation in the direction normal to the drawing sheet. As depicted in FIG. 3, trench structure 200 is periodic having a period equal to the target width. The trench structure includes a line element characterized by a line width. The line element includes multiple layers 202-205 fabricated on a substrate 201. Layers 202-205 are characterized by thickness T₁-T₄, respectively, and each layer is fabricated from its own material. In addition, the trench structure 200 includes a trench element filled with air 206 characterized by a trench width and trench depth.

In some embodiments, SR measurement system 100 is employed to estimate values of the thicknesses T₁-T₄, line fraction, trench fraction, and trench depth associated with trench structure 200. In these embodiments, line fraction is the ratio of line width to target width and trench fraction is the ratio of trench width to target width.

In this example, the estimation of values of the parameters of interest is undertaken in multiple steps. In a first step, initial estimates of line fraction and trench fraction are computed as illustrated by Equations (3) and (4), respectively. The values of line width, trench width, and target width (pitch) are treated as the nominal values associated with the fabrication process, i.e., the programmed values of the fabrication process.

$$FL = Line Fraction ≅ \frac{Line Width}{1.1 \times Pitch} \qquad ( 3 )$$

$$FT = Trench Fraction ≅ 0.5 \times \frac{Trench Width}{1.1 \times Pitch} \qquad ( 4 )$$

In a second step, an initial regression is executed by deep, large pitch semiconductor structure measurement engine 160. The initial regression employs a non-periodic electromagnetic solver. The initial value of trench fraction determined in accordance with Equation (4) is treated as a fixed valued parameter and material thicknesses, T₁-T₄, are also treated as fixed valued parameters using nominal, programmed values. The line fraction parameter is treated as a floating parameter during the initial regression.

The non-periodic electromagnetic solver is employed to compute the reflective complex amplitude associated with the line element, rₗᵢₙₑ, and the trench element, r_{trench}, for each wavelength at the angle of incidence associated with the measurement as illustrated by equations (5) and (6), respectively. In a preferred embodiment, the angle of incidence is zero, i.e., normal to the surface of wafer 123.

$${r}_{line} ( λ , AOI = 0 ) \qquad ( 5 )$$

$${r}_{trench} ( λ , AOI = 0 ) \qquad ( 6 )$$

In the initial regression, the simulated spectral signals, R^{SIM} 164, are computed as an incoherent sum of the reflection coefficients associated with the sub-structures of trench structure 200. Equation (7) illustrates the computation of the incoherent sum of the reflection coefficients, R_{incoherent}, associated with the line and trench sub-structures of trench structure 200 for each wavelength at a zero angle of incidence.

$${R}_{Incoherent} ( λ , AOI = 0 ) = {\vert FL \times {r}_{line} ( λ , AOI = 0 ) \vert}^{2} + {\vert FT \times {r}_{trench} ( λ , AOI = 0 ) \vert}^{2} \qquad ( 7 )$$

In some embodiments, SR metrology system 100 includes a transverse magnetic (TM) measurement channel and a transverse electric (TE) measurement channel. The TM and TE measurement channels correspond to different orientations of the polarization of the illumination light with respect to the structure under measurement. At normal incidence, the TE measurement is associated with a polarization of the illumination light that is aligned with the direction of incidence of the illumination beam and the TM measurement is associated with a polarization of the illumination light that is perpendicular to the direction of incidence of the illumination beam. In general, reflectometry measurements as described herein are performed based on measurement signals collected from the TE measurement channel, the TM measurement channel, or a combination thereof.

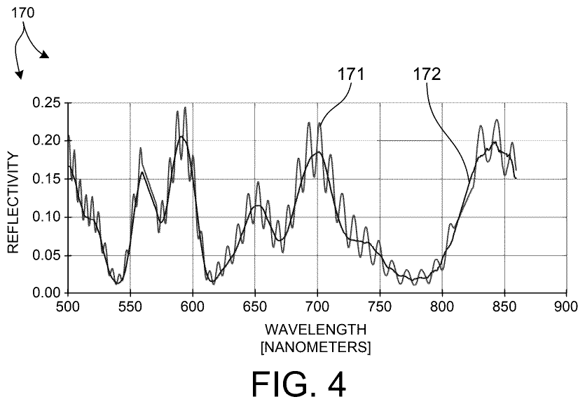

FIG. 4 is a plot 170 depicting two different measured spectral signals illustrated by plotlines 171 and 172, respectively. The measured spectral signals 171 and 172 are associated with measurements of trench structure 200 depicted in FIG. 3 by SR metrology system 100. In this example, the target width, a.k.a., target pitch is approximately 8 micrometers, the trench is approximately 2 micrometers wide and 25 micrometers deep, and the line structure includes a top layer 205 of Silicon Oxide with a thickness, T₄, of approximately 1.2 micrometers, layer 204 of polysilicon with a thickness, T₃, of approximately 0.7 micrometers, layer 203 of Silicon Nitride doped with Silicon with a thickness, T₂, of approximately 0.2 micrometers, and layer 202 of Silicon Oxide with a thickness, T₁, of approximately 23 micrometers.

Plotline 171 illustrates the measured spectral signal associated with a TM measurement channel of SR metrology system 100, and plotline 172 illustrates the measured spectral signal associated with a TE measurement channel of SR metrology system 100. As illustrated in FIG. 4, the TM measurement signal largely tracks the low frequency variations of the TE measurement signal, but the TM measurement signal also includes higher frequency variations that are missing from the TE measurement signals. For some measurements, the TE measurement signals, the TM measurement signals, or a combination thereof, are suitable to extract reasonable estimated values of one or more parameters of interest. For example, measurement of depth of deep, large pitch, hole structures, may be performed using TM measurement signal information, TE signal information, or a combination thereof. However, measurement of depth of deep, large pitch trench structures requires TM measurement signal information, as TE measurement signal information is not sensitive to depth of deep, large pitch trench structures.

In general, the initial regression is focused on resolving values of the line fraction and may be performed based the TM measurement data set or the TE measurement data set. As such, the measured spectral signals, R^{MEAS} 138, illustrated in FIG. 2 may be derived from either the TE measurement channel or the TM measurement channel of SR metrology system 100.

In some examples, an iterative gradient-based regression algorithm, e.g., the N2X algorithm, is employed by error evaluation module 162 to converge to estimated values of the line fraction. The N2X algorithm is an adaptive nonlinear least-squares algorithm. As depicted in FIG. 2, error evaluation module 162 includes the fixed and floating parameter values as input. The residual error signals, R^{ERROR} 165, are computed as the weighted least squares between the measured spectral signals, R^{MEAS} 138, and the simulated spectral signals, R^{SIM} 164.

In a subsequent step, a subsequent regression is executed by deep, large pitch semiconductor structure measurement engine 160. The subsequent regression employs a non-periodic electromagnetic solver. The trench fraction value is treated as a fixed valued parameter determined in accordance with Equation (4). The line fraction value is also treated as a fixed valued parameter, however, the value is the estimated value determined at the prior regression step. Material thicknesses, T₁-T₄, are treated as floating parameters during the subsequent regression. The seed values of the material thicknesses, T₁-T₄, are treated as the nominal, programmed values of the material thicknesses.

The non-periodic electromagnetic solver is employed to compute the reflective complex amplitude associated with the line element, rₗᵢₙₑ, and the trench element, r_{trench}, for each wavelength at the angle of incidence associated with the measurement as described hereinbefore.

In the subsequent regression, the simulated spectral signals, R^{SIM} 164, are computed as an incoherent sum of the reflection coefficients associated with the sub-structures of trench structure 200 as illustrated by Equation (7). The subsequent regression is focused on resolving values of the film thickness parameters, T₁-T₄, and may be performed based the TM measurement data set or the TE measurement data set. As such, the measured spectral signals, R^{MEAS} 138, illustrated in FIG. 2 may be derived from either the TE measurement channel or the TM measurement channel of SR metrology system 100.

In some examples, an iterative gradient-based regression algorithm, e.g., the N2X algorithm, is employed by error evaluation module 162 to converge to estimated values of the film thicknesses T₁-T₄, as described hereinbefore.

In a subsequent step, another subsequent regression is executed by deep, large pitch semiconductor structure measurement engine 160. The subsequent regression employs a non-periodic electromagnetic solver. The trench fraction value is treated as a fixed valued parameter determined in accordance with Equation (4). The line fraction value is treated as a floating parameter, and the seed value is the estimated value determined at a prior regression step. Material thicknesses, T₁-T₄, are again treated as floating parameters, and the seed values of the material thicknesses, T₁-T₄, are treated as the estimated value determined at a prior regression step.

The non-periodic electromagnetic solver is employed to compute the reflective complex amplitude associated with the line element, rₗᵢₙₑ, and the trench element, r_{trench}, for each wavelength at the angle of incidence associated with the measurement as described hereinbefore.

In the subsequent regression, the simulated spectral signals, R^{SIM} 164, are computed as an incoherent sum of the reflection coefficients associated with the sub-structures of trench structure 200 as illustrated by Equation (7). The subsequent regression is focused on resolving values of the film thickness parameters, T₁-T₄, and may be performed based the TM measurement data set or the TE measurement data set. In some examples, it is preferred to use the TM measurement data set for this regression. However, in general, the measured spectral signals, R^{MEAS} 138, illustrated in FIG. 2 may be derived from either the TE measurement channel or the TM measurement channel of SR metrology system 100.

In some examples, an iterative gradient-based regression algorithm, e.g., the N2X algorithm, is employed by error evaluation module 162 to converge to estimated values of the line fraction and film thicknesses T₁-T₄. As such, this regression step effectively refines the estimated values of the line fraction and film thickness parameters.

In a subsequent step, another subsequent regression is executed by deep, large pitch semiconductor structure measurement engine 160. The subsequent regression employs a non-periodic electromagnetic solver. The film thicknesses and line fraction are treated as fixed valued parameters. The values are treated as the estimated values determined at the prior regression step. The trench fraction and the trench depth are treated as floating parameters. The seed value for the trench fraction parameter is the value determined in accordance with Equation (4). In some examples, the seed value for the trench depth parameter is treated as the nominal, programmed value. However, in some other examples, the programmed value is not a reasonable estimate of the trench depth.

In some examples, a set of different seed values spanning a range of possible trench depth values is generated. Furthermore, each of the seed values of the set of seed value of trench depth is treated as the seed value for a different regression instance. In other words, the regression is performed repeatedly, and at each different regression instance, a different seed value of trench depth is employed. By initiating the search for the estimated value of depth from a number of different seed values, it is more likely that one of the regression instances will converge to a depth value associated with a global minimum of the residual error, rather than one of many possible local minima.

In some examples, a set of possible trench depth values is determined based on the number of electromagnetic signal oscillations required to probe the depth of the deep, large pitch target. In one example, a range of possible trench depth values is defined within a maximum trench depth value, TD_{MAX}, defined by Equation (8), and a minimum trench depth value, TD_{MIN}, defined by Equation (9), where the number of trench oscillations, NTO, is determined by Equation (10), λ₁ is the shortest wavelength of the measured spectra under consideration, and λ₂ is the longest wavelength of the measured spectra under consideration, where TD_{NOM}, is the nominal, programmed trench depth.

$${TD}_{Max} = \frac{NumberTrenchOscillations + 2}{2 \times ( {λ}_{1}^{- 1} - {λ}_{2}^{- 1} )} \qquad ( 8 )$$

$${TD}_{Min} = \frac{NumberTrenchOscillations - 2}{2 \times ( {λ}_{1}^{- 1} - {λ}_{2}^{- 1} )} \qquad ( 9 )$$

$$NTO = 2 * {TD}_{Nom} * ( {λ}_{1}^{- 1} - {λ}_{2}^{- 1} ) \qquad ( 10 )$$

The set of possible trench depth values is a sequence of possible trench depth values spaced apart by a predetermined trench depth interval, e.g., one hundred nanometers, that spans a range bracketed by the minimum and maximum trench depth values determined based on Equations (8) and (9). Although the set of possible trench depth values may be determined based on Equations (8)-(10) as described hereinbefore, in general, any suitable definition of the set of possible trench depth values may be contemplated within the scope of this patent document.

The non-periodic electromagnetic solver is employed to compute the reflective complex amplitude associated with the line element, rₗᵢₙₑ, and the trench element, r_{trench}, for each wavelength at the angle of incidence associated with the measurement for each regression instance, i.e., for each regression seeded by a different value of trench depth.

In these regressions, the simulated spectral signals, R^{SIM} 164, are computed as a coherent sum of the reflection coefficients associated with the sub-structures of trench structure 200 as illustrated by Equation (11). Equation (11) illustrates the computation of the coherent sum of the reflection coefficients, R_{coherent}, associated with the line and trench sub-structures of trench structure 200 for each wavelength at a zero angle of incidence.

$$( 11 )$$

$${R}_{Coherent} ( λ , AOI = 0 ) = {\vert FL \times {r}_{line} ( λ , AOI = 0 ) + FT \times {r}_{trench} ( λ , AOI = 0 ) \vert}^{2}$$

The regressions are focused on resolving values of the trench fraction and trench depth and are performed based on the TM measurement data set. As such, for these regressions, the measured spectral signals, R^{MEAS} 138, illustrated in FIG. 2 are derived from the TM measurement channel of SR metrology system 100. In some examples, an iterative gradient-based regression algorithm, e.g., the N2X algorithm, is employed by error evaluation module 162 to converge to estimated values of the trench fraction and trench depth for each different seed value of trench depth.

In a subsequent step, another subsequent regression is executed by deep, large pitch semiconductor structure measurement engine 160. The subsequent regression employs a non-periodic electromagnetic solver. The line fraction, trench fraction, trench depth, and film thicknesses are all treated as floating parameters. The seed values are the estimated values determined at prior regression steps. In some examples, N different values of trench depth are selected as different seed values. Furthermore, each of the N different seed values is treated as the seed value for a different regression instance. The N different values are the estimated values of trench depth associated with the prior regressions that result in the N smallest residual errors. In general, N can be any nonzero integer value up to the number of possible trench depth values in the set of possible trench depth values explored in the prior regression instances.

The non-periodic electromagnetic solver is employed to compute the reflective complex amplitude associated with the line element, rₗᵢₙₑ, and the trench element, r_{trench}, for each wavelength at the angle of incidence associated with the measurement as described hereinbefore. The simulated spectral signals, R^{SIM} 164, are computed as a coherent sum of the reflection coefficients associated with the sub-structures of trench structure 200 as illustrated by Equation (11). The regressions are focused on resolving values of the trench fraction, trench depth, line fraction, and film thicknesses and are performed based on the TM measurement data set. As such, for these regressions, the measured spectral signals, R^{MEAS} 138, illustrated in FIG. 2 are derived from the TM measurement channel of SR metrology system 100. In some examples, an iterative gradient-based regression algorithm, e.g., the N2X algorithm, is employed by error evaluation module 162 to converge to estimated values of the trench fraction, trench depth, line fraction, and film thicknesses for each different seed value of trench depth. In some examples, an iterative gradient-based regression algorithm, e.g., the N2X algorithm, is employed by error evaluation module 162 to converge to estimated values of the trench fraction, trench depth, line fraction, and film thicknesses. As such, this regression step effectively refines the estimated values of the trench fraction, trench depth, line fraction, and film thickness parameters.

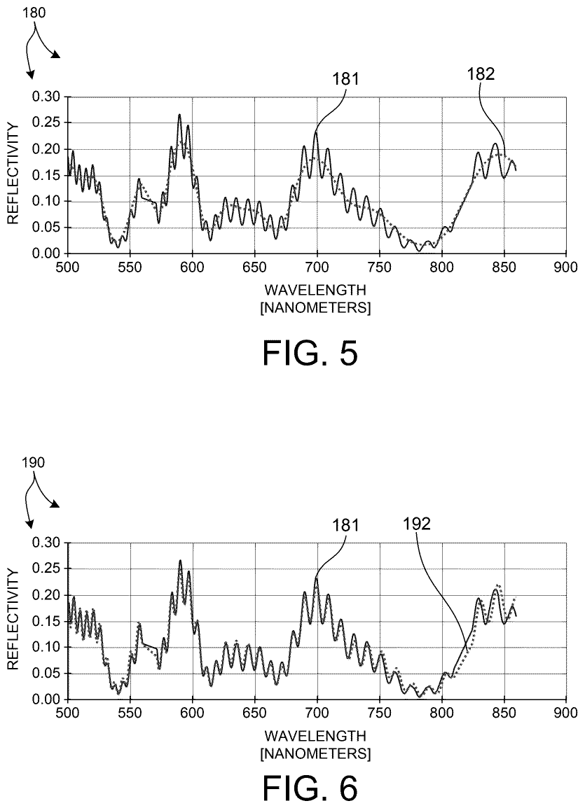

FIG. 5 is plot 180 depicting measured spectral signals illustrated by plotline 181 and corresponding simulated measurement signals 182 after fitting of the trench fraction, trench depth, line fraction, and film thickness parameters. The measured spectral signals 181 are associated with a measurement of trench structure 200 depicted in FIG. 3 by SR metrology system 100. Plotline 181 illustrates the measured spectral signal associated with a TM measurement channel of SR metrology system 100. Plotline 182 corresponds to simulated measurement signals, e.g., R^{SIM} 164, generated based on an incoherent sum of the reflection coefficients associated with the sub-structures of trench structure 200 as illustrated by Equation (7).

FIG. 6 is plot 100 depicting measured spectral signals illustrated by plotline 181 and corresponding simulated measurement signals 192 after fitting of the trench fraction, trench depth, line fraction, and film thickness parameters. As described with reference to FIG. 5, plotline 181 is associated with a measurement of trench structure 200 depicted in FIG. 3 by SR metrology system 100 in a TM mode. Plotline 192 corresponds to simulated measurement signals, e.g., R^{SIM} 164, generated based on a coherent sum of the reflection coefficients associated with the sub-structures of trench structure 200 as illustrated by Equation (11). As illustrated by FIGS. 5 and 6, simulation of measurement signals based on a coherent sum of the reflection coefficients associated with the sub-structures of trench structure 200 captures both the low and high frequency variations of the TM measurement signal. This enables estimation of difficult to measure parameters such as trench depth.

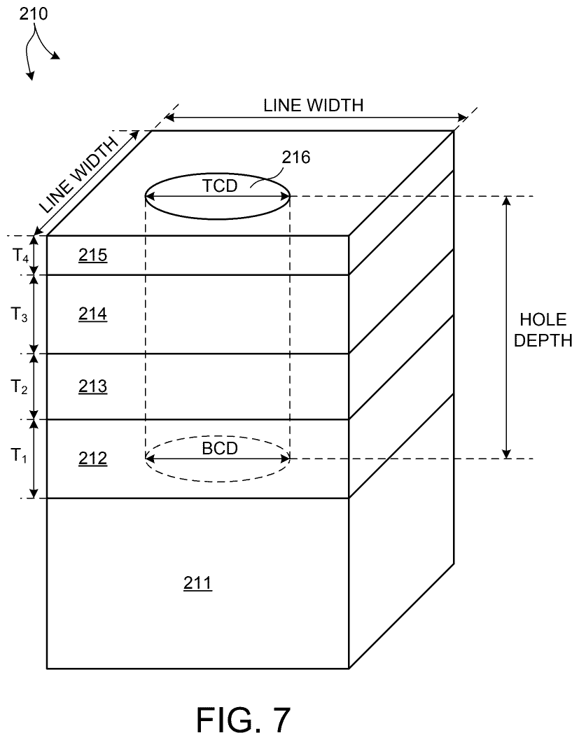

FIG. 7 is a diagram illustrative of a perspective view of a deep, large pitch hole structure 210 in one embodiment. The three dimensional hole-shaped structure is sometimes referred to as a through-silicon via (TSV) model. A top view of the hole-shaped structure has a square line element with a hole element in the middle of the square. The hole is filled with air, and the line is fabricated with multiple film layers. As depicted in FIG. 7, hole structure 210 is periodic having a period equal to the line width. The line element includes multiple layers 212-215 fabricated on a substrate 211. Layers 212-215 are characterized by thickness T₁-T₄, respectively, and each layer is fabricated from its own material. In addition, hole structure 210 includes a hole element filled with air 216 characterized by a top hole diameter, a.k.a., top critical dimension, bottom hole diameter, a.k.a., bottom critical dimension, and hole depth.

In some embodiments, SR measurement system 100 is employed to estimate values of the thicknesses T₁-T₄, line width, BCD, TCD, and hole depth associated with hole structure 210.

In this example, the estimation of values of the parameters of interest is undertaken in multiple steps. In a first step, initial estimates of line fraction and hole fraction are computed as illustrated by Equations (12) and (13), respectively. The values of line width, TCD, and BCD are treated as the nominal values associated with the fabrication process, i.e., the programmed values of the fabrication process.

$$FL = Line Fraction ≅ \frac{{( Line Width )}^{2} - {( \frac{TCD}{2} )}^{2} * π}{{( Line Width )}^{2}} \qquad ( 12 )$$

$$FH = Hole Fraction ≅ \frac{{( \frac{BCD}{2} )}^{2} * π}{{( Line Width )}^{2}} \qquad ( 13 )$$

In a second step, an initial regression is executed by deep, large pitch semiconductor structure measurement engine 160. The initial regression employs a non-periodic electromagnetic solver. The initial value of hole fraction determined in accordance with Equation (13) is treated as a fixed valued parameter and material thicknesses, T-T₄, are also treated as fixed valued parameters using nominal, programmed values. The line fraction parameter is treated as a floating parameter seeded by the value calculated in accordance with Equation (12) during the initial regression.

The non-periodic electromagnetic solver is employed to compute the reflective complex amplitude associated with the line element, rₗᵢₙₑ, and the hole element, rₕₒₗₑ, for each wavelength at the angle of incidence associated with the measurement as illustrated by equations (14) and (15), respectively. In a preferred embodiment, the angle of incidence is zero, i.e., normal to the surface of wafer 123.

$${r}_{line} ( λ , AOI = 0 ) \qquad ( 14 )$$

$${r}_{hole} ( λ , AOI = 0 ) \qquad ( 15 )$$

In the initial regression, the simulated spectral signals, R^{SIM} 164, are computed as an incoherent sum of the reflection coefficients associated with the sub-structures of hole structure 210. Equation (16) illustrates the computation of the incoherent sum of the reflection coefficients, R_{incoherent}, associated with the line and hole sub-structures of hole structure 210 for each wavelength at a zero angle of incidence.

$${R}_{Incoherent} ( λ , AOI = 0 ) = {\vert FL \times {r}_{line} ( λ , AOI = 0 ) \vert}^{2} + {\vert FH \times {r}_{hole} ( λ , AOI = 0 ) \vert}^{2} \qquad ( 16 )$$

In general, the initial regression is focused on resolving values of the line fraction and may be performed based the TM measurement data set or the TE measurement data set. As such, the measured spectral signals, R^{MEAS} 138, illustrated in FIG. 2 may be derived from either the TE measurement channel or the TM measurement channel of SR metrology system 100. In some examples, an iterative gradient-based regression algorithm, e.g., the N2X algorithm, is employed by error evaluation module 162 to converge to estimated values of the line fraction.

In a subsequent step, another regression is executed by deep, large pitch semiconductor structure measurement engine 160. The regression employs a non-periodic electromagnetic solver. The hole fraction value is treated as a fixed valued parameter determined in accordance with Equation (13). The line fraction value is also treated as a fixed valued parameter, however, the value is the estimated value determined at the prior regression step. Hole critical dimensions, BCD and TCD, and material thicknesses, T₁-T₄, are treated as floating parameters during the subsequent regression. The seed values are treated as the nominal, programmed values.

The non-periodic electromagnetic solver is employed to compute the reflective complex amplitude associated with the line element, rₗᵢₙₑ, and the hole element, rₕₒₗₑ, for each wavelength at the angle of incidence associated with the measurement as described hereinbefore.

The simulated spectral signals, R^{SIM} 164, are computed as an incoherent sum of the reflection coefficients associated with the sub-structures of hole structure 210 as illustrated by Equation (16). The regression is focused on resolving values of TCD, BCD, and film thickness parameters, T₁-T₄, and may be performed based the TM measurement data set or the TE measurement data set. As such, the measured spectral signals, R^{MEAS} 138, illustrated in FIG. 2 may be derived from either the TE measurement channel or the TM measurement channel of SR metrology system 100. In some examples, an iterative gradient-based regression algorithm, e.g., the N2X algorithm, is employed by error evaluation module 162 to converge to estimated values of TCD, BCD, and the film thicknesses T₁-T₄.

In another subsequent step, another regression is executed by deep, large pitch semiconductor structure measurement engine 160. The regression employs a non-periodic electromagnetic solver. The hole fraction value is treated as a fixed valued parameter determined in accordance with Equation (13). The line fraction value is treated as a floating parameter, and the seed value is the estimated value determined at a prior regression step. TCD, BCD, and material thicknesses, T₁-T₄, are again treated as floating parameters, and the seed values are treated as the estimated value determined at a prior regression step.

The non-periodic electromagnetic solver is employed to compute the reflective complex amplitude associated with the line element, rₗᵢₙₑ, and the hole element, hole, for each wavelength at the angle of incidence associated with the measurement as described hereinbefore.

The simulated spectral signals, R^{SIM} 164, are computed as an incoherent sum of the reflection coefficients associated with the sub-structures of hole structure 210 as illustrated by Equation (16). The regression is focused on resolving values of line fraction, TCD, BCD, and the film thickness parameters, T₁-T₄, and may be performed based on the TM measurement data set or the TE measurement data set. In some examples, it is preferred to use the TM measurement data set for this regression. However, in general, the measured spectral signals, R^{MEAS} 138, illustrated in FIG. 2 may be derived from either the TE measurement channel or the TM measurement channel of SR metrology system 100.

In some examples, an iterative gradient-based regression algorithm, e.g., the N2X algorithm, is employed by error evaluation module 162 to converge to estimated values of the line fraction, TCD, BCD, and film thicknesses T₁-T₄. As such, this regression step effectively refines the estimated values of the line fraction, TCD, BCD, and the film thickness parameters.

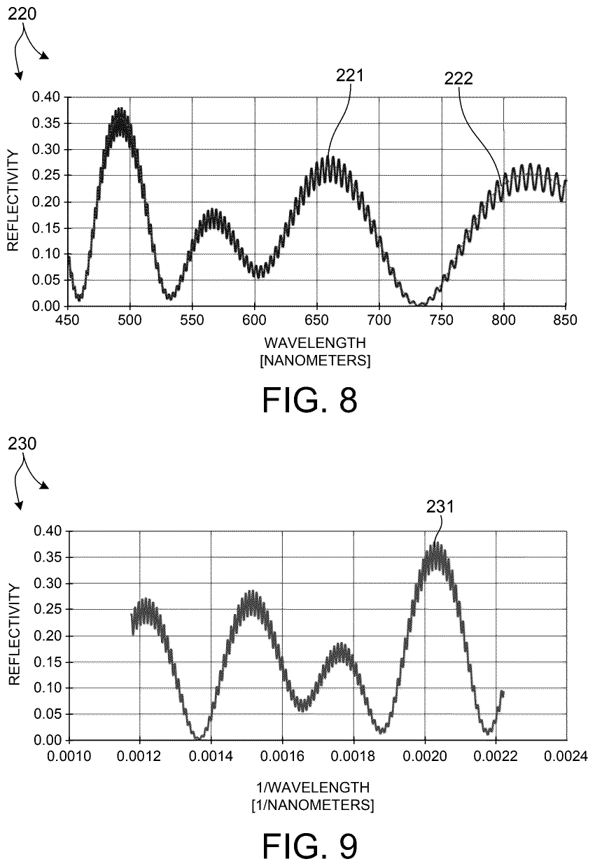

FIG. 8 is plot 220 depicting measured spectral signals illustrated by plotline 221 and corresponding simulated measurement signals 222 after fitting of the line fraction, TCD, BCD, and the film thickness parameters. The measured spectral signals 221 are associated with a measurement of hole structure 210 depicted in FIG. 7 by SR metrology system 100. Plotline 221 illustrates the measured spectral signal associated with a TM measurement channel of SR metrology system 100. Plotline 222 corresponds to simulated measurement signals, e.g., R^{SIM} 164, generated based on an incoherent sum of the reflection coefficients associated with the sub-structures of hole structure 210 as illustrated by Equation (16).

In another subsequent step, one or more regressions are executed by deep, large pitch semiconductor structure measurement engine 160. The subsequent regressions employ a non-periodic electromagnetic solver. TCD, BCD, the film thicknesses, and line fraction are treated as fixed valued parameters. The values are treated as the estimated values determined at the prior regression step. The hole fraction and the hole depth are treated as floating parameters. The seed value for the hole fraction parameter is the value determined in accordance with Equation (14). In some examples, the seed value for the hole depth parameter is treated as the nominal, programmed value. However, in some other examples, the programmed value is not a reasonable estimate of the hole depth.

In some examples, a range of possible seed values associated with depth of a deep, large pitch structure is estimated based on an analysis of the measured spectral signals. In one example, the measured spectral signals are mapped to the inverse wavelength domain. A Fourier transform of the mapped spectral signals is performed such that the measured reflectivity is presented as a function of optical distance. The resulting transformed signals are analyzed to evaluate a range of possible hole depths.

FIG. 9 is plot 230 depicting the measured spectral signals illustrated by plotline 221 of FIG. 8 mapped to the inverse wavelength domain, i.e., plotted with respect to inverse wavelength, rather than wavelength as illustrated in FIG. 8.

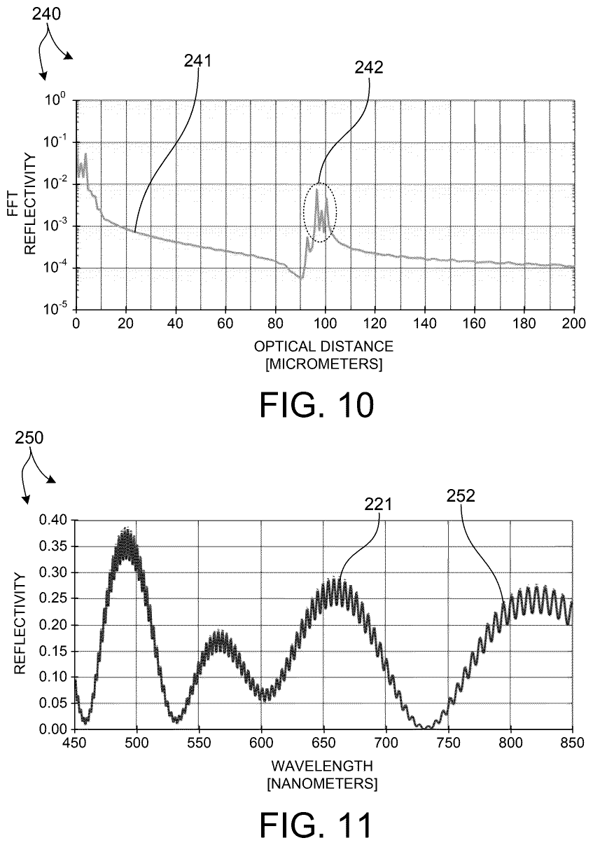

FIG. 10 is plot 240 depicting a plotline 241 illustrative of a Fast Fourier Transform (FFT) of the mapped spectral signals of FIG. 9. As illustrated by FIG. 10, the FFT results in a plot of reflectivity as a function of optical distance. The optical distance is the distance traversed by the measurement light as it enters the structure, reflects, and exits the structure. As such, the optical distance is twice the depth of penetration of light into the structure under measurement. As illustrated in FIG. 10, there is a tight bundle of peaks 242 that fall within a range between approximately 94-102 micrometers. Although, it is unknown which peak corresponds to the hole depth, it can be concluded with high probability that the hole depth is within a range of 47-51 micrometers (half the optical distance).

In some other examples, a range of possible seed values associated with hole depth is estimated based on the number of electromagnetic signal oscillations required to probe the depth of the deep, large pitch target as described with reference to Equations (8)-(10).

In some examples, the set of possible hole depth values is a sequence of possible hole depth values spaced apart by a predetermined trench depth interval, e.g., one hundred nanometers, that spans a range bracketed by the minimum and maximum trench depth values determined based on Equations (8) and (9), or based on the analysis described with reference to FIGS. 8-10.

The non-periodic electromagnetic solver is employed to compute the reflective complex amplitude associated with the line element, rₗᵢₙₑ, and the hole element, rₕₒₗₑ, for each wavelength at the angle of incidence associated with the measurement for each regression instance, i.e., for each regression seeded by a different value of hole depth.

In these regressions, the simulated spectral signals, R^{SIM} 164, are computed as a coherent sum of the reflection coefficients associated with the sub-structures of hole structure 210 as illustrated by Equation (17). Equation (17) illustrates the computation of the coherent sum of the reflection coefficients, R_{coherent}, associated with the line and hole sub-structures of hole structure 210 for each wavelength at a zero angle of incidence.

$${R}_{Coherent} ( λ , AOI = 0 ) = {\vert FL \times {r}_{line} ( λ , AOI = 0 ) + FH \times {r}_{hole} ( λ , AOI = 0 ) \vert}^{2} \qquad ( 17 )$$

The regressions are focused on resolving values of the hole fraction and hole depth, and, in some examples, are performed based on the TM measurement data set. In one example, for these regressions, the measured spectral signals, R^{MEAS} 138, illustrated in FIG. 2 are derived from the TM measurement channel of SR metrology system 100. In some examples, an iterative gradient-based regression algorithm, e.g., the N2X algorithm, is employed by error evaluation module 162 to converge to estimated values of the hole fraction and hole depth for each different seed value of hole depth.

In a subsequent step, another subsequent regression is executed by deep, large pitch semiconductor structure measurement engine 160. The subsequent regression employs a non-periodic electromagnetic solver. The line fraction, hole fraction, hole depth, TCD, BCD, and film thicknesses are all treated as floating parameters. The seed values are the estimated values determined at prior regression steps. In some examples, N different values of hole depth are selected as different seed values. Furthermore, each of the N different seed values is treated as the seed value for a different regression instance. “The N different values are the estimated values of hole depth associated with the prior regressions that result in the N smallest residual errors. In general, N can be any nonzero integer value up to the number of possible hole depth values in the set of possible hole depth values explored in the prior regression instances.

The non-periodic electromagnetic solver is employed to compute the reflective complex amplitude associated with the line element, rₗᵢₙₑ, and the hole element, rₕₒₗₑ, for each wavelength at the angle of incidence associated with the measurement as described hereinbefore. The simulated spectral signals, R^{SIM} 164, are computed as a coherent sum of the reflection coefficients associated with the sub-structures of hole structure 210 as illustrated by Equation (17). The regressions are focused on resolving values of the hole fraction, hole depth, line fraction, TCD, BCD, and film thicknesses, and, in some examples, are performed based on the TM measurement data set. In one example, for these regressions, the measured spectral signals, R^{MEAS} 138, illustrated in FIG. 2 are derived from the TM measurement channel of SR metrology system 100. In some examples, an iterative gradient-based regression algorithm, e.g., the N2X algorithm, is employed by error evaluation module 162 to converge to estimated values of the hole fraction, hole depth, line fraction, TCD, BCD, and film thicknesses for each different seed value of hole depth. In some examples, an iterative gradient-based regression algorithm, e.g., the N2X algorithm, is employed by error evaluation module 162 to converge to estimated values of the hole fraction, hole depth, line fraction, TCD, BCD, and film thicknesses. As such, this regression step effectively refines the estimated values of the hole fraction, hole depth, line fraction, TCD, BCD, and film thicknesses.

FIG. 11 is plot 250 depicting measured spectral signals illustrated by plotline 221 and corresponding simulated measurement signals 252 after fitting of the hole fraction, hole depth, line fraction, TCD, BCD, and film thicknesses. The measured spectral signals 221 are associated with a measurement of hole structure 210 depicted in FIG. 7 by SR metrology system 100. Plotline 221 illustrates the measured spectral signal associated with a TM measurement channel of SR metrology system 100. Plotline 252 corresponds to simulated measurement signals, e.g., R^{SIM} 164, generated based on a coherent sum of the reflection coefficients associated with the sub-structures of hole structure 210 as illustrated by Equation (17).

Although, the aforementioned examples described measurements of deep, large pitch trench and hole structures, in general, the measurement of any deep, large pitch structure in accordance with the methods and systems described herein may be contemplated within the scope of this patent document.

Although, the aforementioned examples described measurements of deep, large pitch trench and hole structures in accordance with specific steps of a multi-step regression, in general, the aforementioned multi-step regression example may include additional steps or fewer steps.

Although, the aforementioned examples describe the use of a non-periodic electromagnetic solver, in general, different steps of a multi-step regression may employ different electromagnetic solvers, including periodic electromagnetic solvers, such as an RCWA solver. For example, a non-periodic solver may be employed when resolving a depth value, and an RCWA solver may be employed to resolve other critical dimension parameters at different steps of a multi-step regression.

In other examples, domain decomposition is applied and a non-periodic solver is employed to resolve a depth value, and an RCWA solver is employed to resolve other critical dimension parameters during the same regression step.

Although, the aforementioned examples describe the use of an iterative gradient-based regression algorithm, in general, different steps of a multi-step regression may employ different regression algorithms.

Although, the aforementioned examples describe the use of a multi-step regression, in general, a global regression algorithm may be employed.

In some examples, a Numerical Aperture averaging calculation can be included as part of the electromagnetic simulation employed to compute reflection coefficients.

In some examples, additional effects, such as edge diffraction, are simulated by the electromagnetic simulation engine when calculating reflection coefficients, e.g., when using a geometric optics or physical optics solver.

In some examples, secondary order reflections are simulated by the electromagnetic simulation engine when calculating reflection coefficients.

In some embodiments, the methods and systems for SR metrology of semiconductor devices described herein are applied to the measurement of deep, large pitch structures. These embodiments enable optical critical dimension (CD), film, and composition metrology for semiconductor devices with deep, large pitch structures (e.g., TSV structures, NAND, VNAND, TCAT, DRAM, etc.), and, more generally, for complex devices that suffer from low light penetration into the structure(s) being measured. As described herein, the term “deep, large pitch structure” refers to any structure characterized by an aspect ratio that exceeds 2:1 or 10:1, and may be as high as 100:1, or higher, with a large electrical pitch, e.g., up to 10 micrometers.

More specifically, a semiconductor metrology system including a SR subsystem enables high throughput characterization of several classes of semiconductor structures that are currently inadequately measured. Measurements include: 1) Measurement of critical dimensions of three dimensional semiconductor packages; 2) Measurement of epitaxial film layers; 3) Measurement of deep, large pitch structures employed in DRAM manufacturing, in particular, the storage node; 4) Measurement of thick, opaque layers such as amorphous carbon films, and 5) Measurement of channel holes, tungsten recess, and other critical metrology challenges in three dimensional NAND manufacturing.

In addition, a SR subsystem enables high throughput characterization of several emerging classes of semiconductor structures that are currently inadequately measured. These measurements include 1) Measurement of critical dimensions and shape of through silicon vias (TSVs); 2) Measurement of critical dimensions and shape of DRAM capacitor structures; 3) Measurement of silicon/silicon carbide epitaxy and composition; 4) Measurement of films employed in three dimensional NAND hard mask layers (e.g., amorphous carbon layers); and 5) Measurement of three dimensional NAND Tungsten Recess and Channel hole profiles.

In some examples, measurements of parameters of interest are performed based on SR techniques including single target techniques, multi-target techniques and feedforward techniques. Accuracy of measured parameters may be improved by any combination of feed sideways analysis, feed forward analysis, and parallel analysis. Feed sideways analysis refers to taking multiple data sets on different areas of the same specimen and passing common parameters determined from the first dataset onto the second dataset for analysis. Feed forward analysis refers to taking data sets on different specimens and passing common parameters forward to subsequent analyses using a stepwise copy exact parameter feed forward approach. Parallel analysis refers to the parallel or concurrent application of a non-linear fitting methodology to multiple datasets where at least one common parameter is coupled during the fitting.

Multiple tool and structure analysis refers to a feed forward, feed sideways, or parallel analysis based on regression, a look-up table (i.e., “library” matching), or another fitting procedure of multiple datasets. Exemplary methods and systems for multiple tool and structure analysis is described in U.S. Pat. No. 7,478,019, issued on Jan. 13, 2009, to KLA-Tencor Corp., the entirety of which is incorporated herein by reference.

In general, a metrology system may also include additional measurement channels such as a spectroscopic ellipsometer, scatterometer, or any combination thereof, in addition to the SR measurement channel described with reference to FIG. 1.

In some embodiments, the SR subsystem described herein employs off-axis illumination, collection, or both, to reject measurement signals generated by reflections from the bottom of the underlying substrate. In these embodiments, the illumination, collection, or both, are arranged at near normal incidence, but specifically avoiding normal incidence (AOI=zero degrees). In some embodiments, normal illumination is employed, but an obscuration mask in the collection path at or near the collection aperture stop or its conjugates, is employed to block the central rays over the numerical aperture such that the back side reflection is not admitted into the measurement optics. This approach enables normal illumination incidence, but suffers from possible disadvantages such as a centrally obscured pupil, light loss, and algorithmic complexity. In some other embodiments, and obscuration is located in the illumination path.

As depicted in FIG. 1, the illustrated SR measurement channel includes a polarizer and an analyzer. However, in general, it is contemplated that any measurement channel may include, or not include, an illumination polarizer, a collection analyzer, an illumination compensator, a collection compensator, in any combination, to perform measurements of the polarized reflectivity of the sample, unpolarized reflectivity of the sample, or both.

In some embodiments, one or more measurement channels of the metrology systems described herein are configured to measure the wafer at different azimuth angles, in addition to different ranges of wavelength and angle of incidence. In some embodiments, a metrology system as described herein is configured to perform measurements of the wafer at azimuth angles of zero and ninety degrees relative to the metrology target. In some embodiments, the metrology system is configured to measure wafer reflectivity over one or more wavelength ranges, one or more AOI ranges, and one or more azimuth angles simultaneously.

Although FIG. 1 describes specific embodiments of a metrology system including a SR subsystem, in general, the measurement techniques described herein apply to any combination of SR and other metrology subsystems. Exemplary SR subsystems include, but are not limited to, polarized SR, unpolarized SR, Mueller matrix SR, spectroscopic scatterometry, scatterometry overlay, angle resolved reflectometry, polarization resolved reflectometery, beam profile reflectometry, etc.

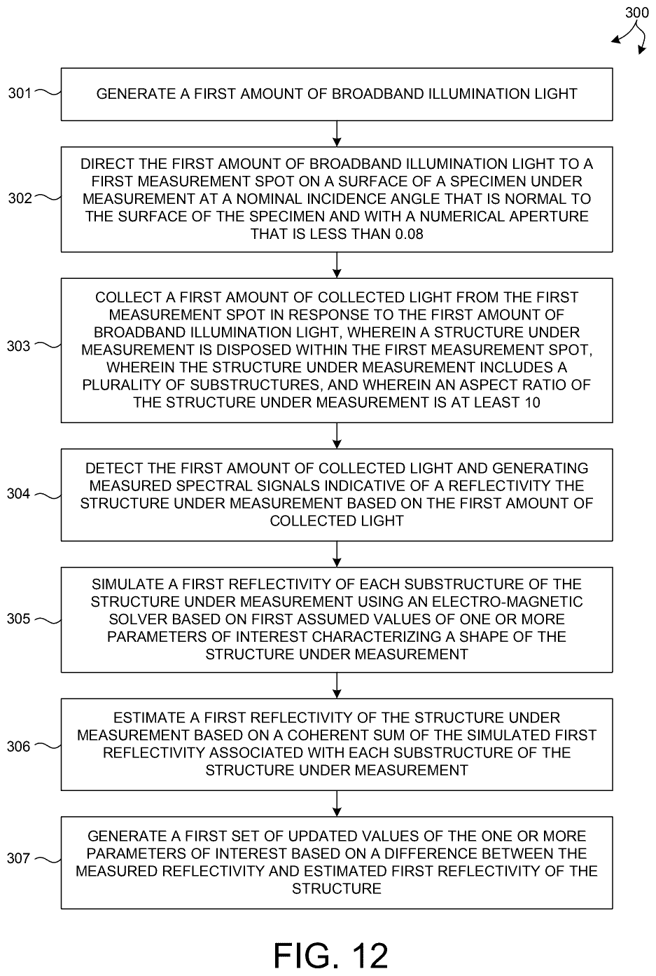

FIG. 12 illustrates a method 300 of performing SR measurements of semiconductor structures in at least one novel aspect. Method 300 is suitable for implementation by a metrology system such as metrology system 100, illustrated in FIG. 1 of the present invention. In one aspect, it is recognized that data processing blocks of method 300 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 301, a first amount of broadband illumination light is generated.

In block 302, the first amount of broadband illumination light is directed to a first measurement spot on a surface of a specimen under measurement at a nominal incidence angle that is normal to the surface of the specimen and with a numerical aperture that is less than 0.08.

In block 303, a first amount of light is collected from the first measurement spot in response to the first amount of broadband illumination light. A structure under measurement is disposed within the first measurement spot. The structure under measurement includes a plurality of substructures, and an aspect ratio of the structure under measurement is at least 10.

In block 304, the first amount of collected light is detected, and measured spectral signals indicative of a reflectivity the structure under measurement are generated based on the first amount of collected light.

In block 305, a first reflectivity of each substructure of the structure under measurement is simulated using an electro-magnetic solver based on first assumed values of one or more parameters of interest characterizing a shape of the structure under measurement.

In block 306, a first reflectivity of the structure under measurement is estimated based on a coherent sum of the simulated first reflectivity associated with each substructure of the structure under measurement.

In block 307, a first set of updated values of the one or more parameters of interest is generated based on a difference between the measured reflectivity and estimated first reflectivity of the structure.

In a further embodiment, system 100 includes one or more computing systems 130 employed to perform measurements semiconductor structures in accordance with the methods described herein. The one or more computing systems 130 may be communicatively coupled to the spectrometer 128. In one aspect, the one or more computing systems 130 are configured to receive measurement data associated with measurements of the structure of the specimen under measurement.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers and imaging detectors in any manner known in the art. For example, the one or more computing systems 130 may be coupled to computing systems associated with the spectrometers and imaging detectors. In another example, each of the spectrometers may be controlled directly by a single computer system coupled to computer system 130.

The computer system 130 of metrology system 100 may be configured to receive and/or acquire data or information from the subsystems of the system (e.g., spectrometers, imaging detectors, and the like) by a transmission medium that may include wireline and/or wireless portions. In this manner, the transmission medium may serve as a data link between the computer system 130 and other subsystems of system 100.

Computer system 130 of metrology system 100 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board metrology system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value 150 determined by computer system 130 may be communicated and stored in an external memory. In this regard, measurement results may be exported to another system.

Computing system 130 may include, but is not limited to, a personal computer system, mainframe computer system, cloud-based computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

In another aspect, the methods and systems for combined metrology of semiconductor devices described herein are applied to the measurement of high aspect ratio (HAR) structures, large lateral dimension structures, or both. The described embodiments enable optical critical dimension (CD), film, and composition metrology for semiconductor devices including hybrid bonding structures, through silicon vias, three dimensional NAND structures, such as vertical-NAND (V-NAND) structures, dynamic random access memory structures (DRAM), etc., manufactured by various semiconductor manufacturers such as Samsung Inc. (South Korea), SK Hynix Inc. (South Korea), Toshiba Corporation (Japan), and Micron Technology, Inc. (United States), etc. These complex devices suffer from low light penetration into the structure(s) being measured.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO2. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
at least one illumination source generating a first amount of broadband illumination light;
an optical objective directing the first amount of broadband illumination light to a first measurement spot on a surface of a specimen under measurement and collecting a first amount of collected light from the first measurement spot in response to the first amount of broadband illumination light, wherein the optical objective directs the first amount of broadband illumination light to the first measurement spot at a nominal incidence angle that is normal to the surface of the specimen and a numerical aperture that is less than 0.08, wherein a structure under measurement is disposed within the first measurement spot, wherein the structure under measurement includes a plurality of substructures, and wherein an aspect ratio of the structure under measurement is at least 10;
a spectrometer having a surface sensitive to incident light, the spectrometer detecting the first amount of collected light and generating measured spectral signals indicative of a reflectivity the structure under measurement based on the first amount of collected light; and
one or more computing systems configured to:
simulate a first reflectivity of each substructure of the structure under measurement using an electro-magnetic solver based on first assumed values of one or more parameters of interest characterizing a shape of the structure under measurement;
estimate a first reflectivity of the structure under measurement based on a coherent sum of the simulated first reflectivity associated with each substructure of the structure under measurement; and
generate a first set of updated values of the one or more parameters of interest based on a difference between the measured reflectivity and estimated first reflectivity of the structure.

2. The metrology system of claim 1, the one or more computing systems further configured to:
simulate a second reflectivity of each substructure of the structure under measurement using the electro-magnetic solver based on second assumed values of one or more parameters of interest characterizing the shape of the structure under measurement;
estimate a second reflectivity of the structure under measurement based on a incoherent sum of the simulated second reflectivity associated with each substructure of the structure under measurement; and
generate a second set of updated values of the one or more parameters of interest based on a difference between the measured reflectivity and estimated second reflectivity of the structure.

3. The metrology system of claim 1, wherein the structure under measurement is characterized by a spatial periodicity of at least five micrometers.

4. The metrology system of claim 3, wherein a size of the first measurement spot on the surface of the specimen is at least twice the spatial periodicity of the structure under measurement.

5. The metrology system of claim 1, wherein a size of the first measurement spot on the surface of the speciment is at least 20 micrometers.

6. The metrology system of claim 1, wherein the first amount of broadband illumination light includes wavelengths spanning a range from 550 nanometers to 850 nanometers.

7. The metrology system of claim 1, wherein the structure under measurement is a trench structure or a hole structure.

8. The metrology system of claim 1, wherein a polarization of the first amount of broadband illumination light incident on the first measurement spot is tranverse magnetic or transverse electric.

9. The metrology system of claim 1, the one or more computing systems further configured to:
estimate the first assumed value of a parameter of interest characterizing a depth of a deep, large pitch structure under measurement based on an analysis of the measured spectral signals, wherein the analysis involves mapping the measured spectral signals to an inverse wavelength domain and transforming the mapped spectral signals to express measured reflectivity as a function of optical distance.

10. The metrology system of claim 1, the one or more computing systems further configured to:
estimate the first assumed value of a parameter of interest characterizing a depth of a deep, large pitch structure under measurement based on an estimated number of electromagnetic signal oscillations required to probe a depth of the deep, large pitch target.

11. The metrology system of claim 1, wherein an illumination Numerical Aperture (NA) of the SR subsystem is between 0.04 and 0.08, and wherein a collection NA of the SR subsystem is between 0.01 and 0.04.

12. A method comprising:
generating a first amount of broadband illumination light;
directing the first amount of broadband illumination light to a first measurement spot on a surface of a specimen under measurement at a nominal incidence angle that is normal to the surface of the specimen and with a numerical aperture that is less than 0.08;
collecting a first amount of collected light from the first measurement spot in response to the first amount of broadband illumination light, wherein a structure under measurement is disposed within the first measurement spot, wherein the structure under measurement includes a plurality of substructures, and wherein an aspect ratio of the structure under measurement is at least 10;
detecting the first amount of collected light and generating measured spectral signals indicative of a reflectivity the structure under measurement based on the first amount of collected light;
simulating a first reflectivity of each substructure of the structure under measurement using an electro-magnetic solver based on first assumed values of one or more parameters of interest characterizing a shape of the structure under measurement;
estimating a first reflectivity of the structure under measurement based on a coherent sum of the simulated first reflectivity associated with each substructure of the structure under measurement; and
generating a first set of updated values of the one or more parameters of interest based on a difference between the measured reflectivity and estimated first reflectivity of the structure.

13. The method of claim 12, further comprising:
simulating a second reflectivity of each substructure of the structure under measurement using the electro-magnetic solver based on second assumed values of one or more parameters of interest characterizing the shape of the structure under measurement;
estimating a second reflectivity of the structure under measurement based on a incoherent sum of the simulated second reflectivity associated with each substructure of the structure under measurement; and
generating a second set of updated values of the one or more parameters of interest based on a difference between the measured reflectivity and estimated second reflectivity of the structure.

14. The method of claim 12, wherein the structure under measurement is characterized by a spatial periodicity of at least five micrometers.

15. The method of claim 14, wherein a size of the first measurement spot on the surface of the specimen is at least twice the spatial periodicity of the structure under measurement.

16. The method of claim 12, wherein a polarization of the first amount of broadband illumination light incident on the first measurement spot is tranverse magnetic or transverse electric.

17. The method of claim 12, further comprising:
estimating the first assumed value of a parameter of interest characterizing a depth of a deep, large pitch structure under measurement based on an analysis of the measured spectral signals, wherein the analysis involves mapping the measured spectral signals to an inverse wavelength domain and transforming the mapped spectral signals to express measured reflectivity as a function of optical distance.

18. The method of claim 12, further comprising:
estimating the first assumed value of a parameter of interest characterizing a depth of a deep, large pitch structure under measurement based on an estimated number of electromagnetic signal oscillations required to probe a depth of the deep, large pitch target.

19. A metrology system comprising:
at least one illumination source generating a first amount of broadband illumination light;
an optical objective directing the first amount of broadband illumination light to a first measurement spot on a surface of a specimen under measurement and collecting a first amount of collected light from the first measurement spot in response to the first amount of broadband illumination light, wherein the optical objective directs the first amount of broadband illumination light to the first measurement spot at a nominal incidence angle that is normal to the surface of the specimen and a numerical aperture that is less than 0.08, wherein a structure under measurement is disposed within the first measurement spot, wherein the structure under measurement includes a plurality of substructures, and wherein an aspect ratio of the structure under measurement is at least 10;
a spectrometer having a surface sensitive to incident light, the spectrometer detecting the first amount of collected light and generating measured spectral signals indicative of a reflectivity the structure under measurement based on the first amount of collected light; and
a non-transitory, computer-readable medium storing instructions that, when executed by one or more processors, causes the one or more processors to:
simulate a first reflectivity of each substructure of the structure under measurement using an electro-magnetic solver based on first assumed values of one or more parameters of interest characterizing a shape of the structure under measurement;
estimate a first reflectivity of the structure under measurement based on a coherent sum of the simulated first reflectivity associated with each substructure of the structure under measurement; and
generate a first set of updated values of the one or more parameters of interest based on a difference between the measured reflectivity and estimated first reflectivity of the structure.

20. The metrology system of claim 19, the non-transitory, computer-readable medium further storing instructions that, when executed by one or more processors, causes the one or more processors to:
simulate a second reflectivity of each substructure of the structure under measurement using the electro-magnetic solver based on second assumed values of one or more parameters of interest characterizing the shape of the structure under measurement;
estimate a second reflectivity of the structure under measurement based on a incoherent sum of the simulated second reflectivity associated with each substructure of the structure under measurement; and
generate a second set of updated values of the one or more parameters of interest based on a difference between the measured reflectivity and estimated second reflectivity of the structure.
